(19) United States
(12) Patent Application Publication
(10) Pub. No.: US 2026/0304923 A1
(43) Pub. Date: Oct. 1, 2026

(54) CHANNEL WIDTH AND QUANTITY VARIATION IN GATE-ALL-AROUND AND FORKSHEET TRANSISTORS

(71) Applicant: Intel Corporation, Santa Clara, CA (US)

(72) Inventors: Xia Li, San Diego, CA (US); Patrick Morrow, Portland, OR (US); Charles H. Wallace, Portland, OR (US); Quan Shi, Portland, OR (US)

(73) Assignee: Intel Corporation, Santa Clara, CA (US)

(21) Appl. No.: 19/092,442

(22) Filed: Mar. 27, 2025

(51) Int. Cl. H10D 84/83; H10D 30/00; H10D 30/01; H10D 30/43; H10D 30/47; H10D 62/10; H10D 84/01

(52) U.S. Cl. CPC H10D 84/8311; H10D 30/47; H10D 30/502; H10D 62/121; H10D 84/8312; H10D 84/83138; H10D 84/832; H10D 30/014; H10D 30/017; H10D 30/0191; H10D 30/43; H10D 84/0128; H10D 84/0151

(57) ABSTRACT

Techniques to form gate-all-around (GAA) and/or forksheet semiconductor devices that have varying semiconductor channel widths and varying numbers of semiconductor channel bodies (e.g., nanoribbons, nanosheets, nanowires). The techniques can be used in any number of transistor technologies, but are particularly useful in vertically stacked transistor configurations (e.g., stacked in a vertical z-direction from the substrate surface) and/or configurations that extend laterally in a horizontal x-or-y-direction). In an example, the n-channel device and the p-channel device may both be GAA or forksheet transistors each having any number of channel bodies extending in the same direction where the n-channel device is located vertically above the p-channel device (or vice versa). Any number of adjacent devices may be patterned from a single fin to include varying channel body widths. In addition, any of the devices may include different numbers of channel bodies extending between corresponding source or drain regions.

### BACKGROUND

As integrated circuits continue to scale downward in size, a number of challenges arise. For instance, reducing the size of memory and logic cells or otherwise increasing device density is becoming increasingly more difficult. One possible solution to increase device density is to stack transistor devices in a vertical direction. There are many non-trivial challenges involved with the fabrication of such stacked devices, especially when attempting to vary the properties of the associated device structures.

### BRIEF DESCRIPTION OF THE DRAWINGS

FIG. 1A is a cross-sectional view across a series of stacked semiconductor devices having different numbers of nanoribbons with different widths, in accordance with an embodiment of the present disclosure.

FIG. 1B is plan view across the series of stacked semiconductor devices of FIG. 1A having different numbers of nanoribbons with different widths, in accordance with an embodiment of the present disclosure.

FIG. 1C is a cross-sectional view across another series of stacked semiconductor devices having different numbers of nanoribbons with different widths, in accordance with an embodiment of the present disclosure.

FIGS. 2A and 2B are cross-sectional and plan views, respectively, of a first stage in an example process for forming stacked semiconductor devices having different numbers of nanoribbons with different widths, in accordance with some embodiments of the present disclosure.

FIGS. 3A and 3B are cross-sectional and plan views, respectively, of another stage in the example process for forming stacked semiconductor devices having different numbers of nanoribbons with different widths, in accordance with some embodiments of the present disclosure.

FIGS. 4A and 4B are cross-sectional and plan views, respectively, of another stage in the example process for forming stacked semiconductor devices having different numbers of nanoribbons with different widths, in accordance with some embodiments of the present disclosure.

FIGS. 5A and 5B are cross-sectional and plan views, respectively, of another stage in the example process for forming stacked semiconductor devices having different numbers of nanoribbons with different widths, in accordance with some embodiments of the present disclosure.

FIGS. 6A and 6B are cross-sectional and plan views, respectively, of another stage in the example process for forming stacked semiconductor devices having different numbers of nanoribbons with different widths, in accordance with some embodiments of the present disclosure.

FIGS. 7A and 7B are cross-sectional and plan views, respectively, of another stage in the example process for forming stacked semiconductor devices having different numbers of nanoribbons with different widths, in accordance with some embodiments of the present disclosure.

FIGS. 8A and 8B are cross-sectional and plan views, respectively, of another stage in the example process for forming stacked semiconductor devices having different numbers of nanoribbons with different widths, in accordance with some embodiments of the present disclosure.

FIGS. 9A and 9B are cross-sectional and plan views, respectively, of another stage in the example process for forming stacked semiconductor devices having different numbers of nanoribbons with different widths, in accordance with some embodiments of the present disclosure.

FIGS. 10A and 10B are cross-sectional and plan views, respectively, of another stage in the example process for forming stacked semiconductor devices having different numbers of nanoribbons with different widths, in accordance with some embodiments of the present disclosure.

FIGS. 11A and 11B are cross-sectional and plan views, respectively, of another stage in the example process for forming stacked semiconductor devices having different numbers of nanoribbons with different widths, in accordance with some embodiments of the present disclosure.

FIGS. 12A and 12B are cross-sectional and plan views, respectively, of another stage in the example process for forming stacked semiconductor devices having different numbers of nanoribbons with different widths, in accordance with some embodiments of the present disclosure.

FIGS. 13A and 13B are cross-sectional and plan views, respectively, of another stage in the example process for forming stacked semiconductor devices having different numbers of nanoribbons with different widths, in accordance with some embodiments of the present disclosure.

FIGS. 14A and 14B are cross-sectional and plan views, respectively, of another stage in the example process for forming stacked semiconductor devices having different numbers of nanoribbons with different widths, in accordance with some embodiments of the present disclosure.

FIG. 15 illustrates a plan view of an example portion of an integrated circuit having a series of adjacent devices where at least one of the devices is a forksheet device, in accordance with an embodiment of the present disclosure.

FIG. 16 illustrates a plan view of an example portion of an integrated circuit having a series of adjacent devices where each of the devices is a forksheet device, in accordance with another embodiment of the present disclosure.

FIG. 17 illustrates a cross-section view of a chip package containing one or more semiconductor dies, in accordance with some embodiments of the present disclosure.

FIG. 18 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form gate-all-around (GAA) and/or forksheet semiconductor devices that have varying semiconductor channel widths and varying numbers of semiconductor channel bodies (e.g., nanoribbons, nanosheets, nanowires). The techniques can be used in any number of transistor technologies, but are particularly useful in a stacked transistor configuration (e.g., stacked in a vertical z-direction from the substrate surface) and/or configurations that extend in the lateral x- or y-direction. For instance, an n-channel device and a p-channel device may both be GAA transistors each having any number of nanoribbons extending in the same direction, where the n-channel device is located vertically above the p-channel device (or vice versa). In an example, any number of adjacent GAA and/or forksheet devices may be patterned from a single fin to include varying nanoribbon (e.g., channel) widths. In addition, any of the devices may include different numbers of nanoribbons or nanosheets extending between corresponding source or drain regions. Devices that include a relatively smaller width and a relatively fewer number of nanoribbons may be better suited for low power operations while occupying a smaller footprint on the die, while devices that include a relatively larger width and a relatively larger number of nanoribbons may be better suited for high power operations. Note that terms like nanoribbon or nanosheet or nanowire are used interchangeably herein, and may also be referred to as semiconductor channels or semiconductor bodies or semiconductor channel bodies, or the like. In this manner, a given gate-all-around transistor configuration and a forksheet configuration may include nanoribbons or nanosheets or nanowires, and use of such channel body terms are not intended to exclude a transistor configuration. Numerous variations and embodiments will be apparent in light of this disclosure.

### General Overview

As previously noted above, there remain a number of non-trivial challenges with respect to designing gate-all-around (GAA) semiconductor devices. In the case of stacked nanoribbon transistors, for example, it is difficult to make modifications to the stacked structures, which may be desirable to form transistors having different effective channel sizes. For example, transistors having larger effective channel sizes are more suitable for high power operations such as being used for power switching, while transistors having smaller effective channel sizes are more suitable for low power operations, such as logic switching or memory. Since the low-power transistors are generally smaller, they can also take up less real estate on the die, thus increasing their packing density. Modifying the effective channel size of GAA devices may be performed by changing geometric properties of the nanoribbons, such as their length, width, thickness, and the number of nanoribbons. Properties such as the channel length and channel thickness may be fixed due to fabrication and process node constraints. However, varying properties such as nanoribbon width and number of nanoribbons across different devices is challenging.

Thus, and in accordance with an embodiment of the present disclosure, techniques are provided herein to form various stacked GAA and/or forksheet architectures having different channel body (e.g., nanoribbon/nanosheet/nanowire) widths and with a different number of nanoribbons/nanosheets in each device. In this way, adjacent stacked devices may have a different number of nanoribbons/nanosheets/nanowires from each other while also having different nanoribbon/nanosheet/nanowire widths. Such techniques can be used to form any variation of device sizes using stacked GAA and/or forksheet devices. It should be understood that the transistor embodiments described herein are also applicable to non-stacked transistor configurations, where adjacent devices have different nanoribbon/nanosheet/nanowire widths and a different number of total nanoribbons/nanosheets/nanowires. In one example, a first set of stacked devices each include a first total number of nanoribbons having a first width, a second set of stacked devices adjacent to the first set of stacked devices each include a second total number of nanoribbons greater than the first total number of nanoribbons having a second width greater than the first width, and a third set of stacked devices adjacent to the second set of stacked devices each include a third total number of nanoribbons greater than the second total number of nanoribbons having a third width greater than the second width. Each set of stacked devices may include one n-channel device and one p-channel device.

According to some embodiments, the varying number of nanoribbons between adjacent devices may be formed by epitaxially growing alternating patterned layers of semiconductor material with un-patterned layers of sacrificial material. The pattern within the stacked layers of semiconductor material define how many nanoribbons are to be included in each device. According to some embodiments, the varying widths of the adjacent devices may be formed by patterning a fin having a varying width along its length before the formation of any sacrificial gate structures across the fin. Further details of these processes will be described in more detail herein.

According to an embodiment, an integrated circuit includes a first plurality of semiconductor nanoribbons extending from a first source or drain region in a first direction, a second plurality of semiconductor nanoribbons extending from a second source or drain region in the first direction, a first gate structure extending over the first plurality of semiconductor nanoribbons in a second direction different from the first direction, and a second gate structure extending over the second plurality of semiconductor nanoribbons in the second direction. The first plurality of semiconductor nanoribbons have a first width in the second direction, and the second plurality of semiconductor nanoribbons have a second width in the second direction that is greater than the first width. The second source or drain region is aligned with the first source or drain region along the first direction. A total number of nanoribbons in the first plurality of semiconductor nanoribbons is less than a total number of nanoribbons in the second plurality of semiconductor nanoribbons.

According to another embodiment, an integrated circuit includes a first plurality of semiconductor nanoribbons extending from a first source or drain region in a first direction, a second plurality of semiconductor nanoribbons extending from a second source or drain region in the first direction, and a dielectric structure extending along a second direction different from the first direction and arranged substantially equidistant between the first source or drain region and the second source or drain region along the first direction. The first plurality of semiconductor nanoribbons have a first width in the second direction, and the second plurality of semiconductor nanoribbons have a second width in the second direction that is greater than the first width. The second source or drain region is aligned with the first source or drain region along the first direction. A total number of nanoribbons in the first plurality of semiconductor nanoribbons is less than a total number of nanoribbons in the second plurality of semiconductor nanoribbons.

The techniques are especially suited for use with gate-all-around and forksheet transistors such as nanowire, nanoribbon, and nanosheet transistors. The source and drain regions can be, for example, epitaxial regions that are deposited during an etch-and-replace source/drain forming process. The dopant-type in the source and drain regions will depend on the polarity of the corresponding transistor. The gate electrode can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the changing widths of the nanoribbons (or other channel body) of adjacent devices along a same fin. In some examples, the devices will also have a different number of nanoribbons, such that devices with nanoribbons of smaller width have fewer nanoribbons compared to devices with nanoribbons of greater width.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

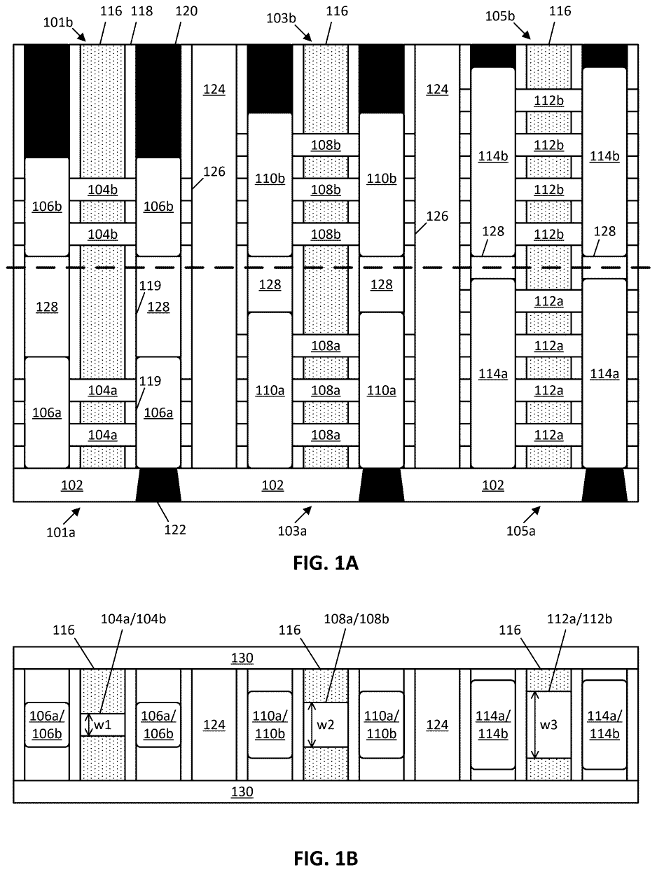

FIG. 1A is a cross sectional view of a portion of an integrated circuit that includes several GAA devices in a stacked configuration, according to an embodiment of the present disclosure. The cross section view is taken lengthwise (perpendicular to gate structure) in a first direction while the gates run into and out of the page in a second direction, and devices are vertically stacked over one another in a third direction substantially orthogonal to the first and second directions. FIG. 1A illustrates three adjacent GAA devices (101a, 103a, and 105a) below the dashed line and three adjacent GAA devices (101b, 103b, and 105b) above the dashed line stacked directly over GAA devices 101a, 103a, and 105a below the dashed line. Any of the illustrated GAA devices may also be forksheet devices, as will be discussed in more detail herein.

The semiconductor material used in each of the semiconductor devices may be formed from or on a semiconductor substrate. According to some embodiments, the substrate is removed following the completion of all topside processing and is replaced with a base dielectric structure 102. Base dielectric structure 102 may represent any number of dielectric layers and/or materials. In some examples, base dielectric structure 102 includes one or more layers of silicon dioxide.

The GAA devices may include semiconductor regions (also called channel regions), such as one or more nanoribbons extending in a first direction (e.g., across the page) between a corresponding first source or drain region and a corresponding second source or drain region. Any of the source or drain regions may include epitaxially grown material from the ends of the nanoribbons.

According to some embodiments, the GAA devices can include a different number of semiconductor nanoribbons. In the illustrated example, a first semiconductor device 101a has two nanoribbons 104a extending between source or drain regions 106a, a second semiconductor device 101b above first semiconductor device 101a has two nanoribbons 104b extending between source or drain regions 106b, a third semiconductor device 103a has three nanoribbons 108a extending between source or drain regions 110a, a fourth semiconductor device 103b above third semiconductor device 103a has three nanoribbons 108b extending between source or drain regions 110b, a fifth semiconductor device 105a has four nanoribbons 112a extending between source or drain regions 114a, and a sixth semiconductor device 105b above fifth semiconductor device 105a has four nanoribbons 112b extending between source or drain regions 114b. In this example, GAA devices stacked directly over one another include the same number of nanoribbons. Other total numbers of nanoribbons can be used as well for any of the GAA devices. According to some embodiments, GAA devices with a greater total number of nanoribbons have a larger effective gate width (e.g., greater channel surface area), making them more suitable for high power switching operations.

Any of the source or drain regions 106/110/114 may act as either a source region or a drain region, depending on the application and dopant profile. Any semiconductor materials suitable for source and drain regions can be used (e.g., group IV and group III-V semiconductor materials). In any such cases, the composition and doping of the source or drain regions may be the same or different, depending on the polarity of the transistors. In an example, the lower GAA devices (101a, 103a, 105a) are p-channel devices having a high concentration of p-type dopants in the associated source or drain regions 106a, 110a, and 114a, and the upper GAA devices (101b, 103b, 105b) n-channel devices having a high concentration of n-type dopants in the associated source or drain regions 106b, 110b, and 114b. Example p-type dopants include boron and example n-type dopants include phosphorous or arsenic. Any number of source and drain configurations and materials can be used. In some examples, p-type source or drain regions include silicon germanium doped with boron and n-type source or drain regions include silicon doped with phosphorous.

According to some embodiments, the various source or drain regions have heights in the third direction that correspond to the number of nanoribbons that are coupled to. In such examples, source or drain regions 106a and 106b are generally shorter than source or drain regions 110a and 110b, which in turn are generally shorter than source or drain regions 114a and 114b. However, in some embodiments, additional epitaxial growth from substrate semiconductor material can cause the bottom source or drain regions 106a/110a/114a to have substantially the same height, or at least have the differences between their heights be less pronounced than the height differences between the top source or drain regions 106b/110b/114b.

A gate structure 116 is provided over the nanoribbons of each GAA device in a shared gate architecture, where the gates of directly stacked devices are in conductive contact, according to some embodiments. In some other embodiments, a dielectric layer is present between the nanoribbons of GAA devices 101a, 103a, 105a and the nanoribbons of GAA devices 101b, 103b, 105b to produce a split gate architecture where a first gate structure around nanoribbons 104a/108a/112a is electrically isolated from a second gate structure around nanoribbons 104b/108b/112b. The embodiments illustrated herein use the shared gate architecture but are equally applicable to split gate architectures.

Gate structure 116 extends over the nanoribbons of each GAA device in a second direction (e.g., into and out of the page) to form the transistor gate of each corresponding device. Each gate structure 116 may include a corresponding gate electrode and gate dielectric. The gate electrode may be made up of a conductive fill and one or more metal workfunction layers, according to some embodiments. The gate dielectric may represent any number of dielectric layers. The conductive fill may include any sufficiently conductive material such as a metal, metal alloy, or doped polysilicon. In some examples, the conductive fill includes tungsten (W), although other metals or conductive materials may be used, such as aluminum (Al), molybdenum (Mo), ruthenium (Ru), cobalt (Co), or doped polysilicon. In some embodiments, p-channel devices have a gate electrode with one or more workfunction layers of molybdenum nitride (MoN). Other metal workfunction layers of p-channel devices can include tantalum nitride (TaN) and tungsten (W). In some embodiments, n-channel devices have a gate electrode with one or more workfunction layers of titanium aluminum carbide. Other metal workfunction layers of n-channel devices can include tantalum nitride (TaN). The gate dielectric may include any suitable gate dielectric material(s). In some embodiments, the gate dielectric includes a layer of native oxide material (e.g., silicon dioxide germanium dioxide, or SiGe oxide) on the nanoribbons, and a layer of high-k dielectric material (e.g., hafnium oxide or aluminum oxide) on the native oxide.

According to some embodiments, spacer structures 118 and inner spacers 119 are present along the sidewalls of gate structures 116. Spacer structures 118 and inner spacers 119 may be any suitable dielectric material, such as silicon nitride, silicon oxynitride, or silicon oxycarbonitride, and provide separation between a given gate structure and the adjacent source or drain region. Inner spacers 119 may separate adjacent nanoribbons from one another along a third direction (e.g., a vertical direction).

According to some embodiments, any number of frontside contacts 120 are provided on at least a portion of a top surface of the upper source or drain regions 106b/110b/114b. Frontside contacts 120 can include any suitable conductive material, such as tungsten, molybdenum, ruthenium, cobalt, or other metals. Frontside contacts 120 may be formed during the same metal deposition process(es) such that they all include the same conductive material. As seen in FIG. 1A, frontside contacts 120 may have different depths depending on the corresponding heights of source or drain regions 106b/110b/114b. In some embodiments, frontside contacts 120 have substantially the same depth depending on the arrangement of source or drain regions 106b/110b/114b. For example, FIG. 1C illustrates an arrangement where nanoribbons 104b and 108b are near the top of the stack such that source or drain regions 106b and 110b, respectively form near the top of the stack to reduce the depth of frontside contacts 120. The smaller frontside contacts 120 may reduce contact resistance and parasitic capacitance. In any case, the top surfaces of frontside contacts 120 may be polished to be substantially coplanar with a top surface of spacer structures 118.

According to some embodiments, a backside contact 122 is provided beneath any of the lower source or drain regions 106a/110a/114a. Backside contact 122 may include any of the same materials noted above for frontside contacts 120. In some examples, backside contact 122 and frontside contacts 120 include the same conductive material. Backside contact 122 may connect to backside power or ground rails, or to a signal routing interconnect structure. According to some embodiments, additional dielectric layers and conductive elements can be formed beneath base dielectric structure 102 to create a backside interconnect structure (such as a power delivery network and/or signal routing network).

According to some embodiments, the width of backside contact 122 tapers inwards as it rises towards the bottom surface of the source or drain regions. This tapering may be caused by a backside RIE process used to form the cavities through base dielectric structure 102. In some examples, a first width of backside contact 122 along the first direction at the bottom surface of base dielectric structure 102 is greater than a second width of backside contact 122 along the first direction at the bottom surface of the source or drain regions by at least 3 nm. Backside contact 122 may be lithographically aligned to land on at least a portion of the bottom surface of the source or drain regions.

According to some embodiments, one or more fin isolation structures 124 may be formed adjacent to the stacked devices that cut across one or more fins to isolate devices on either side of the fin isolation structures 124. Fin isolation structures 124 may include one or more dielectric materials that extend in the second direction within a gate trench to cut through any number of fins present within the gate trench. In the illustrated example, fin isolation structures 124 extend along the second direction (e.g., into and out of the page) between adjacent source or drain regions of different GAA devices. Fin isolation structures 124 may include any suitable dielectric material, such as silicon nitride or any other high-k dielectric material. According to some embodiments, fin isolation structures 124 extend in the third direction along at least an entire height of the adjacent stacked GAA devices. A top surface of fin isolation structures 124 may be substantially coplanar with a top surface of spacer structures 118. Fin isolation structures 124 may not be needed in situations where adjacent GAA devices along the first direction are intended to share a given source or drain region (or where dummy transistors are employed). According to some embodiments, semiconductor portions 126 may extend in the first direction between fin isolation structures 124 and adjacent source or drain regions.

According to some embodiments, the space between bottom source or drain regions 106a/110a/114a and top source or drain regions 106b/110b/114b, may be filled with a dielectric material to form a middle dielectric layer 128 to isolate the regions from one another. Middle dielectric layer 128 may include any suitable dielectric material, such as silicon dioxide, silicon oxynitride, or silicon oxycarbonitride.

As discussed above, the various GAA devices may have different nanoribbon widths (e.g., dimension in the second direction). FIG. 1B illustrates a plan view taken across either the top or bottom GAA devices from FIG. 1A. Nanoribbons 104a/104b from GAA devices 101a and 101b have a first width w1, nanoribbons 108a/108b from GAA devices 103a and 103b have a second width w2 that is greater than first width w1, and nanoribbons 112a/112b from GAA devices 105a and 105b have a third width w3 that is greater than second width w2. In some examples, first width w1 is between 10 nm and 15 nm, second width w2 is between 15 nm and 20 nm, and third width w3 is between 20 nm and 25 nm. In some examples, second width w2 is at least 2-10 nm greater than first width w1, and third width w3 is at least 2-10 nm greater than second width w2.

From the plan perspective illustrated in FIG. 1B, one or more gate cuts 130 can be seen extending along the first direction across gate structures 116. Gate cuts 130 may include any suitable dielectric material, such as silicon dioxide, silicon oxynitride, or silicon oxycarbonitride, and may extend in the third direction through at least an entire height of gate structures 116.

### Fabrication Methodology

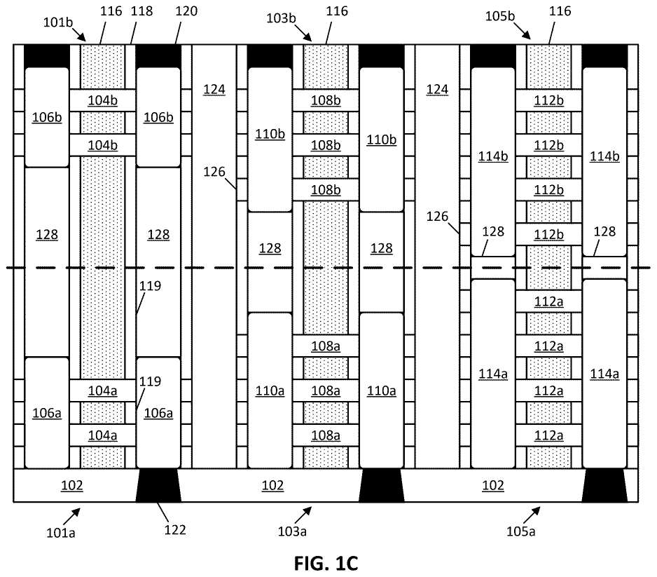

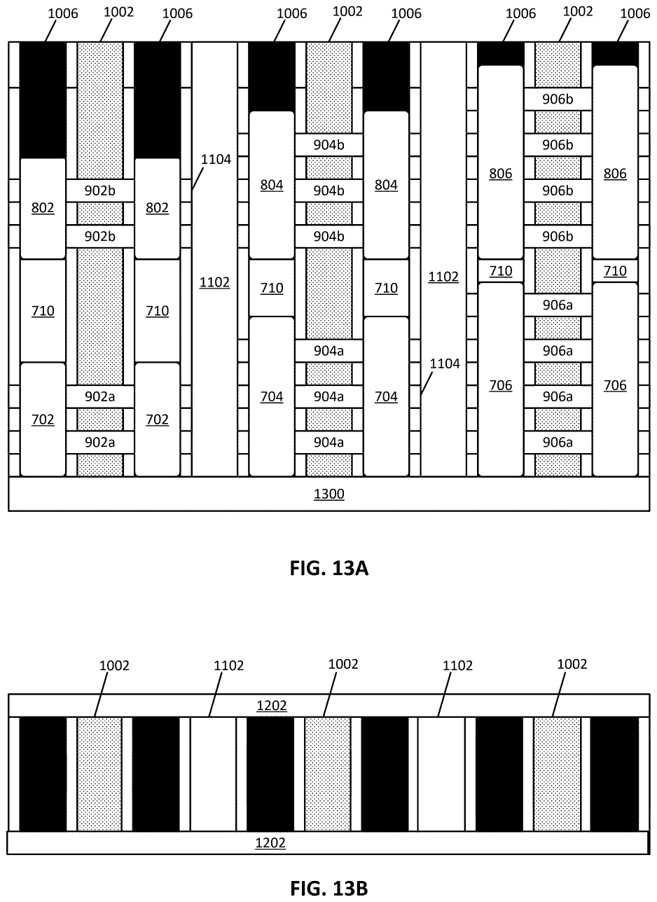

FIG. 2A-14A and 2B-14B include cross-sectional and plan views, respectively, that collectively illustrate an example process for forming an integrated circuit that includes stacked semiconductor devices having different numbers of nanoribbons with different widths, in accordance with an embodiment of the present disclosure. FIG. 2A-14A represent a similar cross-sectional view as that of FIG. 1A, while FIG. 2B-14B represent a similar plan view as that of FIG. 1B. Each set of figures sharing the same letter shows an example structure that results from the process flow up to that point in time, so the depicted structure evolves as the process flow continues, culminating in the structure shown in FIGS. 14A and 14B. The illustrated integrated circuit structure may be part of a larger integrated circuit that includes other integrated circuitry not depicted. Example materials and process parameters are given, but other materials and process parameters may be used as well, as will be appreciated in light of this disclosure.

FIGS. 2A and 2B illustrate cross-sectional and plan views, respectively, of a device having a series of material layers formed over the substrate, according to an embodiment of the present disclosure. Alternating material layers may be deposited over substrate 200, including a first layer stack 201, a second layer stack 203, and a spacer layer 205 between first layer stack 201 and second layer stack 203. Each of first and second layer stacks 201 and 203 includes sacrificial layers 204 alternating with semiconductor layers 206. Any number of alternating sacrificial layers 204 and semiconductor layers 206 may be deposited within each of first layer stack 201 and second layer stack 203. Additionally, any number of layer stacks and spacer layers may be deposited over substrate 200.

Substrate 200 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 200 can be a semiconductor-on-insulator substrate having a desired semiconductor layer over a buried insulator layer (e.g., silicon over silicon dioxide). Alternatively, substrate 200 can be a multilayer substrate or superlattice suitable for forming nanowires or nanoribbons or nanosheets (e.g., alternating layers of silicon and SiGe, or alternating layers indium gallium arsenide and indium phosphide). Any number of substrates can be used.

According to some embodiments, semiconductor layers 206 have a different material composition than sacrificial layers 204. In some embodiments, sacrificial layers 204 are silicon germanium (SiGe) while semiconductor layers 206 include a semiconductor material suitable for use as a nanoribbon such as silicon (Si), SiGe, germanium, or III-V materials like indium phosphide (InP) or gallium arsenide (GaAs). In examples where SiGe is used in each of semiconductor layers 206 and in sacrificial layers 204, the germanium concentration is different between semiconductor layers 206 and sacrificial layers 204. For example, sacrificial layers 204 may include a higher germanium content compared to semiconductor layers 206. Spacer layer 205 may include the same material as sacrificial layers 204. In some examples, spacer layer 205 can be any material that exhibits a high etch selectivity with the material of semiconductor layers 206.

While dimensions can vary from one example embodiment to the next, the thickness of each semiconductor layer 206 may be between about 4 nm and about 20 nm. In some embodiments, the thickness of each semiconductor layer 206 is substantially the same (e.g., within 1-2 nm). The thickness of each of sacrificial layers 204 may be about the same as the thickness of each semiconductor layer 206 (e.g., about 4-20 nm). Each of semiconductor layers 206 and sacrificial layers 204 may be deposited using any known material deposition technique, such as chemical vapor deposition (CVD), plasma-enhanced chemical vapor deposition (PECVD), physical vapor deposition (PVD), or atomic layer deposition (ALD), or epitaxial growth.

According to some embodiments, the alternating layer structure in each of first layer stack 201 and second layer stack 203 includes lithographically patterned semiconductor layers 206′. In the illustrated example, semiconductor layers 206′ have been etched such that they do not extend as far as other semiconductor layers 206. The etched portions of the semiconductor layers may be filled with sacrificial material to form additional sacrificial layers 204′. Briefly, a given semiconductor layer 206 may be etched using a mask and suitable selective etching techniques to form patterned semiconductor layer 206′. Next, sacrificial material may be deposited across the structure and polished back to form adjacent sacrificial layers 204′. This process may be repeated to form any number of patterned semiconductor layers 206′. Any number and any pattern of semiconductor layers 206′ can be provided that alternate with sacrificial layers 204. The number and pattern of semiconductor layer 206′ can be used to determine the number of nanoribbons that will be present in the devices formed from various segments of the layer stack, as will be discussed in more detail herein. FIG. 2B illustrates a plan view showing how the topmost semiconductor layer 206′ has been patterned such that a top surface of semiconductor layer 206′ is substantially coplanar with a top surface of the adjacent sacrificial layer 204′.

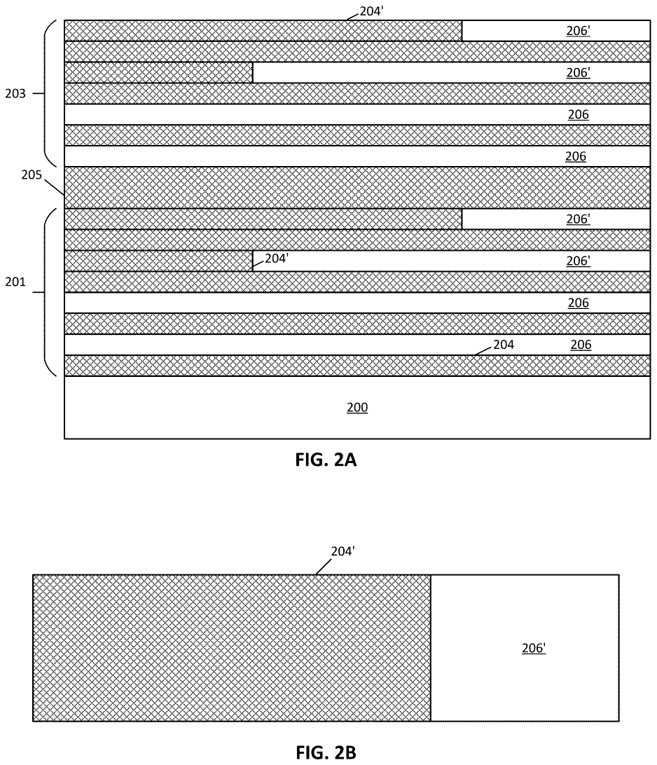

FIGS. 3A and 3B depict the cross-section and plan views, respectively, of the structure shown in FIGS. 2A and 2B, following the formation of a cap layer 301 and the subsequent formation of a fin beneath cap layer 301, according to an embodiment. Cap layer 301 may be any suitable hard mask material such as a carbon hard mask (CHM) or silicon nitride. Cap layer 301 may be patterned into rows to form corresponding rows of fins from the alternating layer stack of sacrificial layers and semiconductor layers. Cap layer 301 extends along the top of each fin in a first direction, as seen in FIG. 3A.

According to some embodiments, an anisotropic etching process through the layer stack continues into at least a portion of substrate 200. Portions of substrate 200 beneath the fins are not etched and yield subfin regions. The etched portion of substrate 200 may be filled with a dielectric fill 302 that acts as shallow trench isolation (STI) between adjacent fins. Dielectric fill 302 may be any dielectric material such as silicon dioxide. The subfin regions represent remaining portions of substrate 200 between dielectric fill 302, and directly beneath the fins according to some embodiments.

According to some embodiments, the fin shape has a varying width along its length, as shown in FIG. 3B. In the illustrated example, the fin includes step changes in its width along the second direction to form different regions, such as a first region 304 having a first width, a second region 306 having a second width greater than the first width, and a third region 308 having a third width greater than the second width.

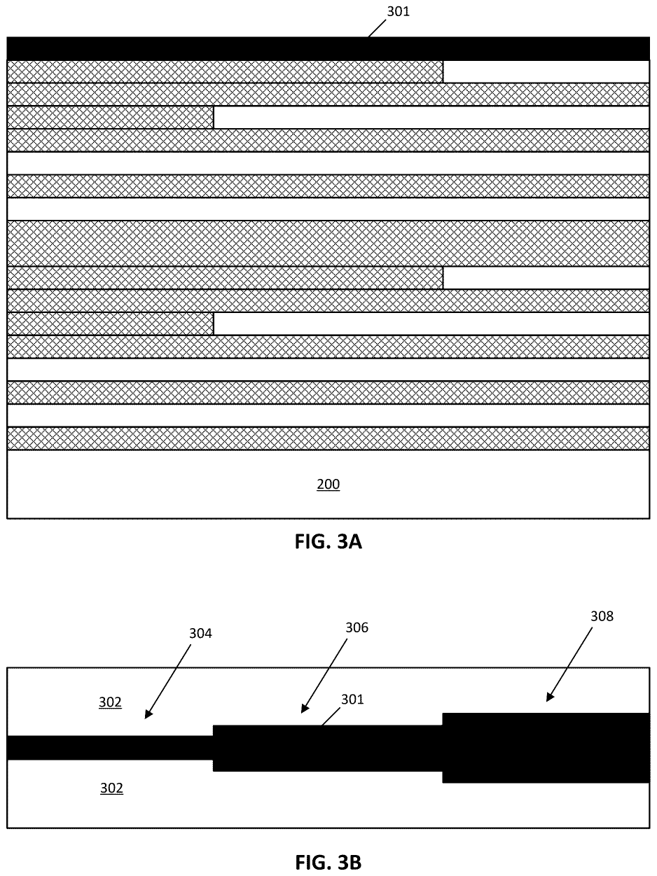

FIGS. 4A and 4B depict the cross-section and plan views, respectively, of the structure shown in FIGS. 2A and 2B, following the formation of sacrificial gates 402, according to some embodiments. A gate masking layer may first be patterned in strips that extend orthogonally across the fin (e.g., in the second direction) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gate 402 may be any material that can be selectively removed without damaging the semiconductor material of the fin. In some examples, sacrificial gate 402 includes polysilicon.

According to some embodiments, spacer structures 404 (also referred to as gate spacers or upper gate spacers) are formed along the sidewalls of sacrificial gates 402. Spacer structures 404 may be deposited and then etched back such that spacer structures 404 remain mostly only on sidewalls of any exposed structures. In the plan view of FIG. 4B, spacer structures 404 may also be formed along sidewalls of the exposed fin over dielectric fill 302. Such sidewall spacers on the fin can be removed during later processing when forming the source or drain regions. According to some embodiments, spacer structures 404 may be any suitable dielectric material, such as silicon nitride, silicon carbon nitride, or silicon oxycarbonitride. In one such embodiment, spacer structures 404 comprise a nitride and dielectric fill 302 comprises an oxide, so as to provide a degree of etch selectivity during final gate processing. Other etch selective dielectric schemes (e.g., oxide/carbide, carbide/nitride) can be used as well for spacer structures 404 and dielectric fill 302. In other embodiments, spacer structures 404 and dielectric fill 302 are compositionally the same or otherwise similar, where etch selectivity is not employed.

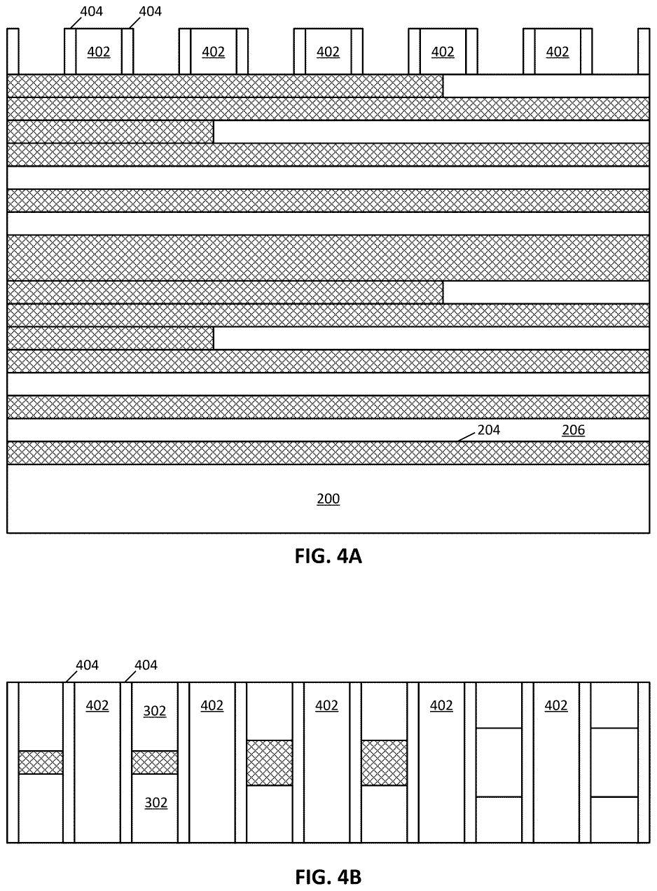

FIGS. 5A and 5B depict the cross-section and plan views, respectively, of the structure shown in FIGS. 2A and 2B, following the removal of exposed portions of the fin not protected by sacrificial gates 402 and spacer structures 404, according to some embodiments. The exposed fin portions may be removed using any anisotropic etching process, such as reactive ion etching (RIE). The removal of the exposed fin portions creates source or drain trenches that alternate with gate trenches (currently filled with sacrificial gates 402) along the first direction, according to some embodiments. In some examples, the RIE process continues to etch into a portion of substrate 200.

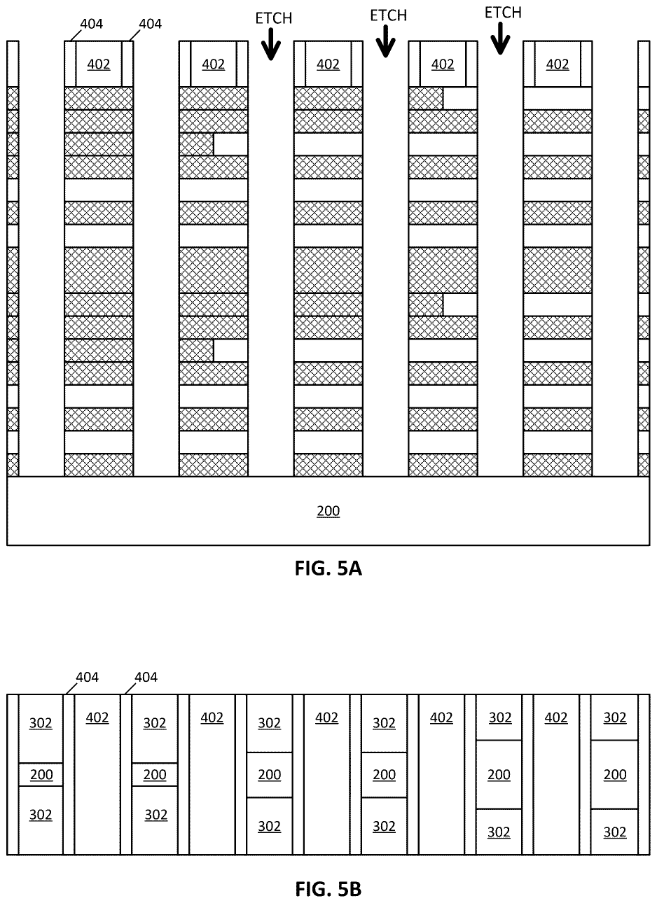

FIGS. 6A and 6B depict the cross-section and plan views, respectively, of the structure shown in FIGS. 5A and 5B, following the removal of portions of sacrificial layers 204/204′ and spacer layer 205 and subsequent formation of internal spacers 602 (sometimes called inner spacer or lower gate spacers), according to an embodiment of the present disclosure. An isotropic etching process may be used to selectively recess the exposed ends of sacrificial layers 204/204′ and spacer layer 205 (e.g., while etching comparatively little of semiconductor layers 206/206′). Internal spacers 602 may have a material composition that is similar to or the exact same as spacer structures 404. Accordingly, internal spacers 602 may be any dielectric material that exhibits high etch selectively to semiconductor materials such as silicon and/or silicon germanium. Internal spacers 602 may be, for example, conformally deposited over the sides of the fin structure using a conformal deposition process like CVD or ALD and then etched back using an isotropic etching process to expose the ends of semiconductor layers 206/206′. According to some embodiments, internal spacers 602 have a similar width (e.g., along the first direction) to spacer structures 404.

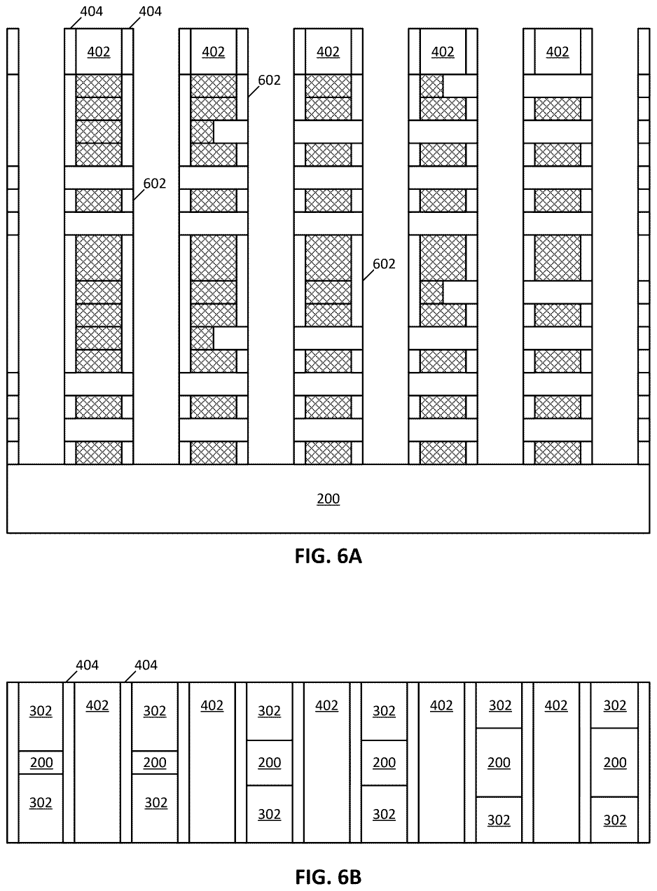

FIGS. 7A and 7B depict cross-section views of the structure shown in FIGS. 6A and 6B, respectively, following the formation of bottom source or drain regions 702, 704, and 706 within the source/drain trenches, according to some embodiments. According to some embodiments, a liner 708 is formed to block the formation of source or drain material at the top semiconductor layers (e.g., those layers above spacer layer 205). Liner 708 may be conformally deposited using a CVD technique, such as ALD, and may have a thickness between about 1 nm and about 4 nm. Any suitable lithography techniques may be used to pattern liner 708 to cover the top semiconductor layers while leaving the bottom semiconductor layers exposed.

According to some embodiments, the bottom source or drain regions 702, 704, and 706 are epitaxially grown from the exposed semiconductor material at the ends of the bottom semiconductor layers 206/206′. Since the majority of the epitaxial growth occurs from exposed ends of the semiconductor layers 206/206′, the heights of the bottom source or drain regions 702, 704, and 706 may be different to correspond with the number of adjacent semiconductor layers 206/206′. In some other examples, the heights of bottom source or drain regions 702, 704, and 706 may be substantially the same (e.g., the same as the height of source or drain regions 706) due to added epitaxial growth from exposed portions of substrate 200. In some example embodiments, the bottom source or drain regions 702, 704, and 706 are all NMOS source or drain regions (e.g., epitaxial silicon) or are all PMOS source or drain regions (e.g., epitaxial SiGe). Note from FIG. 7B that the widths of bottom source or drain regions 702, 704, and 706 may be different to correspond with the different widths of the adjacent fin portions.

According to some embodiments, a dielectric fill 710 is provided within the source/drain trench over (and potentially adjacent to) the bottom source or drain regions 702, 704, and 706. Dielectric fill 710 may be any dielectric material, such as silicon dioxide. In some examples, dielectric fill 710 is deposited and subsequently etched back using any suitable isotropic etching process until the top surface of dielectric fill 710 is at least below a top surface of spacer layer 205.

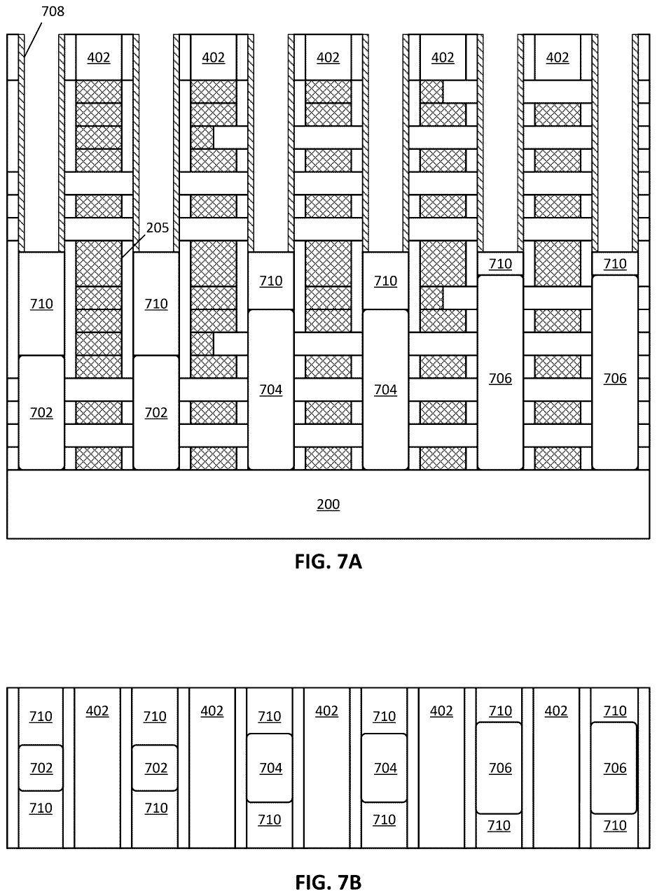

FIGS. 8A and 8B depict cross-section views of the structure shown in FIGS. 7A and 7B, respectively, following the formation of top source or drain regions 802, 804, and 806 within the source/drain trenches, according to some embodiments. The top source or drain regions 802, 804, and 806 are epitaxially grown from the exposed semiconductor material at the ends of the top semiconductor layers 206/206′. Accordingly, the heights of the top source or drain regions 802, 804, and 806 may be different to correspond with the number of adjacent semiconductor layers 206/206′. In some example embodiments, the top source or drain regions 802, 804, and 806 are all NMOS source or drain regions (e.g., epitaxial silicon) or are all PMOS source or drain regions (e.g., epitaxial SiGe), and may be the opposite type from bottom source or drain regions 702, 704, and 706.

According to some embodiments, a top dielectric layer 810 may be formed over the top of (and potentially adjacent to) source or drain regions 802, 804, and 806. In some embodiments, a top surface of top dielectric layer 810 is polished or otherwise planarized to be substantially level with a top surface of spacer structures 404 or sacrificial gates 402. The top surface of top dielectric layer 810 may be polished using chemical mechanical polishing (CMP). Top dielectric layer 810 may be any dielectric material, such as silicon dioxide.

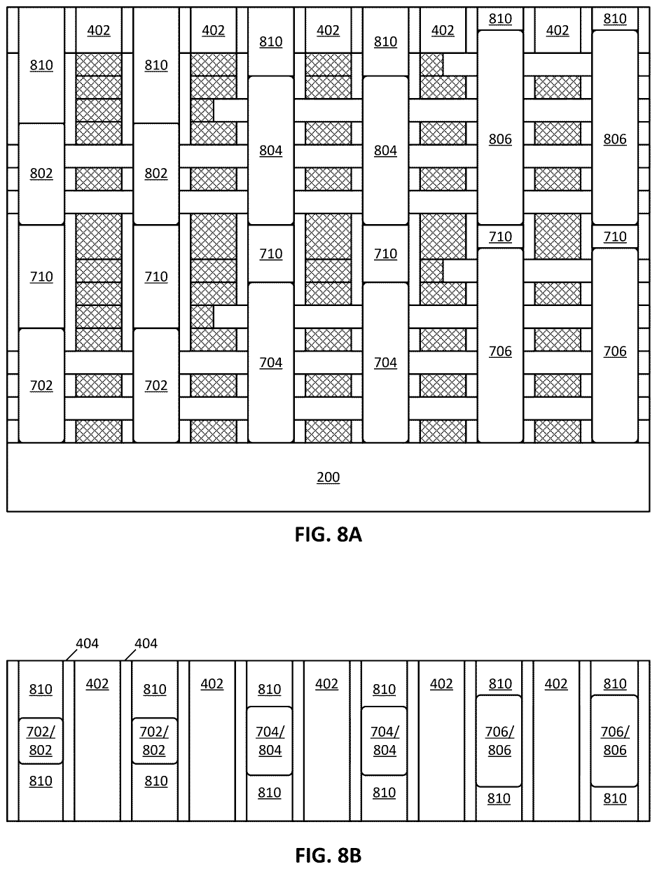

FIGS. 9A and 9B depict cross-section views of the structure shown in FIGS. 8A and 8B, respectively, following the removal of sacrificial gates 402, sacrificial layers 204/204′, and spacer layer 205, according to some embodiments. In examples where gate masking layers are still present, they may be removed at this time. Once sacrificial gates 402 are removed, the remaining fin portions extending between spacer structures 404 are exposed.

Once the fins have been exposed, sacrificial layers 204/204′ and spacer layer 205 are selectively removed to leave behind suspended nanoribbons 902a extending between corresponding source or drain regions 702, nanoribbons 902b extending between corresponding source or drain regions 802, nanoribbons 904a extending between corresponding source or drain regions 704, nanoribbons 904b extending between corresponding source or drain regions 804, nanoribbons 906a extending between corresponding source or drain regions 706, and nanoribbons 906b extending between corresponding source or drain regions 806. Each vertical set of nanoribbons extending in the first direction between a set of source or drain regions represents the semiconductor region (also called channel region) of a different semiconductor device. It should be understood that any of the nanoribbons may also be nanowires, or nanosheets if part of a forksheet arrangement, and such terms are used interchangeably herein, as described above. Sacrificial gates 402 and sacrificial layers 204/204′ and spacer layer 205 may be removed using the same isotropic etching process or different isotropic etching processes.

According to some embodiments, ends of one or more of semiconductor layers 206′ are suspended within the gate trench between spacer structures 404. These particular gate trenches may act as dummy regions (e.g., having non-functioning or disconnected transistors). Note also in the plan view of FIG. 9B how the widths of the semiconductor layers 206/206′ change within the transition or dummy regions.

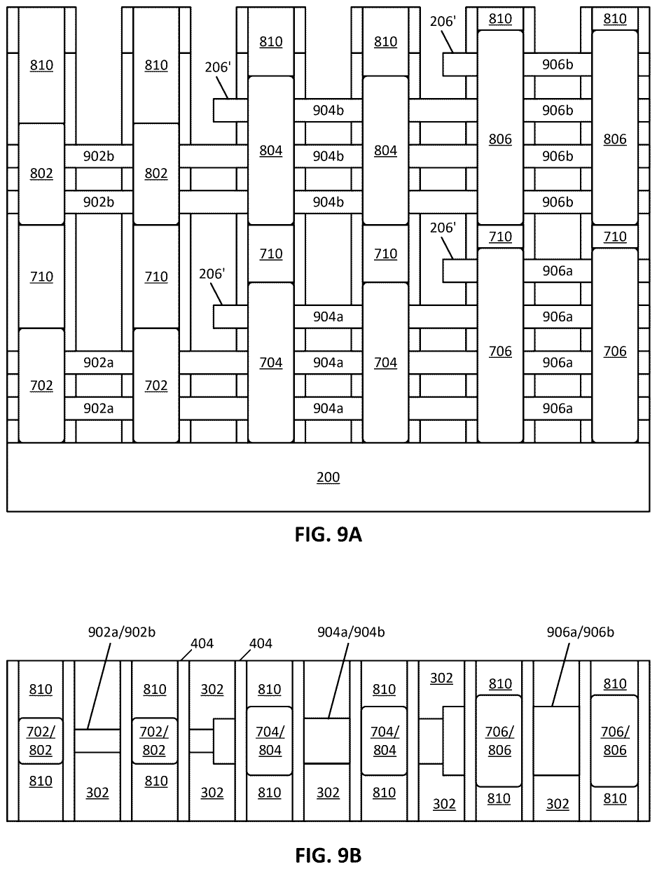

FIGS. 10A and 10B depict cross-section views of the structure shown in FIGS. 9A and 9B, respectively, following the formation of gate structures 1002 within the gate trenches and gate structures 1004 within the dummy regions, according to some embodiments. Additionally, frontside contacts 1006 may be formed on the top surfaces of topside source or drain regions 802, 804, and 806. Gate structures 1002 and 1004 may be substantially the same structures with the same materials and formed at the same time.

As noted above, gate structures 1002 and 1004 each include a gate dielectric and a gate electrode. The gate dielectric may be conformally deposited around the nanoribbons using any suitable deposition process, such as ALD. The gate dielectric may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric is hafnium oxide with a thickness between about 1 nm and about 5 nm. In some embodiments, the gate dielectric may include one or more silicates (e.g., titanium silicate, tungsten silicate, niobium silicate, and silicates of other transition metals). The gate dielectric may be a multilayer structure, in some examples. For instance, the gate dielectric may include a first layer on the nanoribbons, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on the gate dielectric to improve its quality when a high-k dielectric material is used. In some embodiments, the high-k material can be nitridized to improve its aging resistance.

The gate electrode may be deposited over the gate dielectric and can be any standard or proprietary gate structure. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, one or more workfunction layers, resistance-reducing layers, and/or barrier layers. The workfunction layers can include, for example, p-type workfunction materials (e.g., tungsten) for PMOS gates, or n-type workfunction materials (e.g., titanium aluminum carbide or titanium nitride) for NMOS gates. Recall the workfunction layers formed around bottom nanoribbons 902a/904a/906a can be different from the workfunction layers formed around top nanoribbons 902b/904b/906b, according to some example embodiments. Accordingly, each gate structure 1002 may also be represented as two gate structures, with one gate structure extending along the second direction over the bottom nanoribbons 902a/904a/906a and a second gate structure extending along the second direction over the top nanoribbons 902b/904b/906b.

According to some embodiments, frontside contacts 1006 may be formed through top dielectric layer 810 to contact the top surfaces of source or drain regions 802, 804, and 806. In some examples, frontside contacts 1006 extend through top dielectric layer 810 thus leaving behind a portion of top dielectric layer 810. Frontside contacts 1006 may include any suitable conductive material, such as tungsten, cobalt, molybdenum, or ruthenium, for making electrical contact with the underlying source or drain regions 802, 804, and 806. Although not illustrated, any number of frontside interconnect layers may be formed over the semiconductor devices. The interconnect layers include dielectric layers, conductive vias, and conductive layers to carry power and/or signals to various transistor elements.

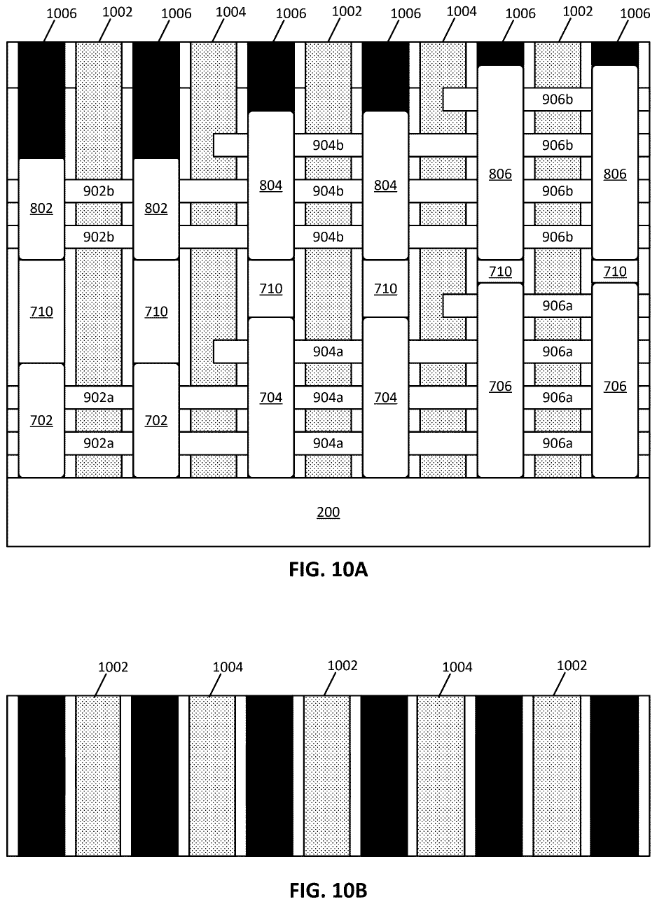

FIGS. 11A and 11B depict cross-section views of the structure shown in FIGS. 10A and 10B, respectively, following the formation of dielectric structures 1102, according to some embodiments. One or more anisotropic etching processes using RIE may be performed to remove gate structures 1004 within the dummy regions along with any exposed semiconductor layers 206/206′ in the dummy regions. The resulting open trenches are then filled with one or more dielectric materials to form dielectric structures 1102. According to some embodiments, dielectric structures 1102 act as isolation structures that electrically isolate GAA devices from one another along the first direction. Dielectric structures 1102 may extend in the third direction along at least an entire height of the adjacent gate structures 1002. A top surface of dielectric structures 1102 may be polished to be substantially coplanar with a top surface of spacer structures 404. Dielectric structures 1102 may include any suitable dielectric material, such as silicon dioxide, silicon nitride, or silicon oxynitride.

According to some embodiments, semiconductor layer portions 1104 remain extending between dielectric structures 1102 and adjacent source or drain regions. Semiconductor layer portions 1104 may be coplanar with any of the suspended nanoribbons, and represent portions of semiconductor layers 206/206′ that remain behind following the formation of dielectric structures 1102, according to some embodiments.

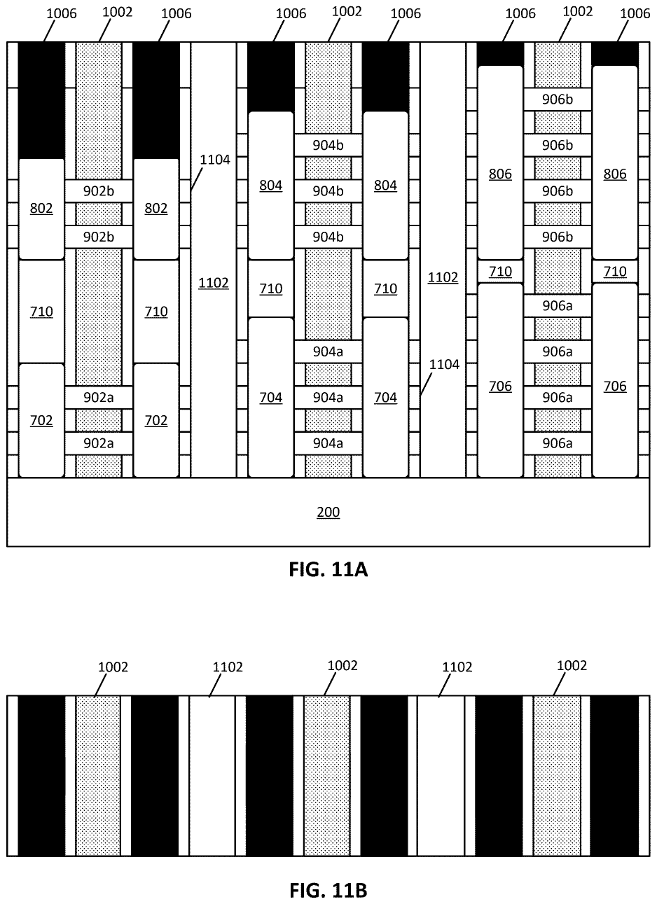

FIGS. 12A and 12B depict cross-section views of the structure shown in FIGS. 11A and 11B, respectively, following the formation of one or more gate cuts 1202, according to some embodiments. Similarly to the formation of dielectric structures 1102, any number of RIE processes may be used to form gate cut trenches extending along the first direction across any number of gate structures 1002. The gate cut trenches may then be filled with one or more suitable dielectric materials to form gate cuts 1202. In some examples, gate cuts 1202 include silicon dioxide, silicon nitride, or silicon oxynitride. In some examples, the order of forming gate cuts 1202 and dielectric structures 1102 is swapped such that gate cuts 1202 are formed first followed by dielectric structures 1102.

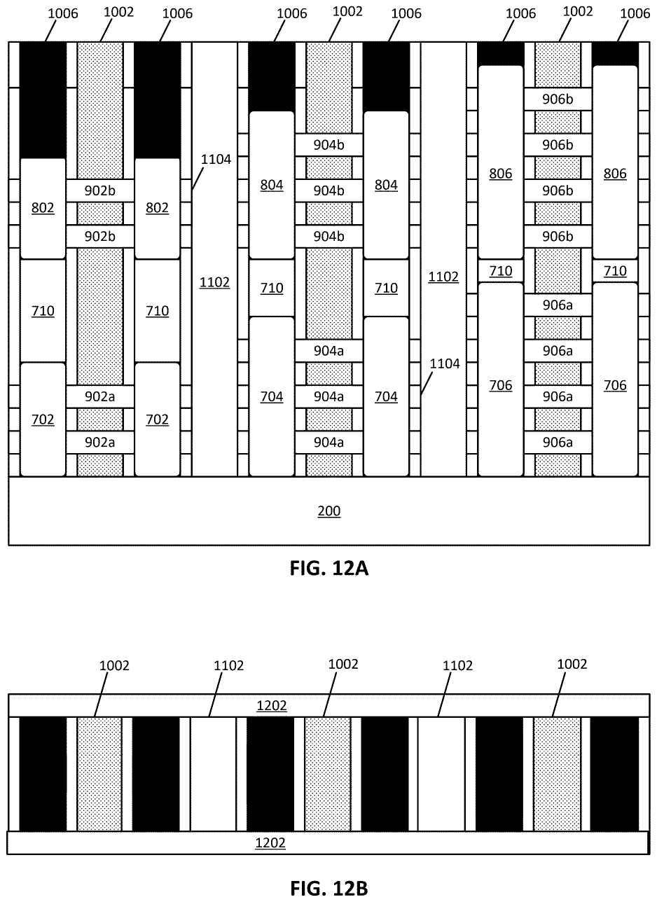

FIGS. 13A and 13B depict cross-section views of the structure shown in FIGS. 12A and 12B, respectively, following the backside removal of substrate 200 and subsequent formation of base dielectric structure 1300, according to some embodiments. Any number of polishing, grinding, or etching processes may be used to remove the bulk portion of substrate 200. According to some embodiments, substrate 200 is removed until a bottom surface of dielectric fill 302 adjacent to the subfin regions is exposed. The backside exposed subfin regions may then be etched away using any suitable isotropic etching process to yield backside cavities. According to some embodiments, one or more additional dielectric layers may be deposited within the backside cavities to form a part of base dielectric structure 1300. Base dielectric structure 1300 may also include previously-formed dielectric fill 302. According to some embodiments, a bottom surface of base dielectric structure 1300 may be polished to be a substantially planar surface.

FIGS. 14A and 14B depict cross-section views of the structure shown in FIGS. 13A and 13B, respectively, following the formation of backside contacts 1402 through base dielectric structure 1300, according to some embodiments. A directional etching process may be performed to create any number of backside cavities through base dielectric structure 1300, according to some embodiments. For example, a RIE process may be used to anisotropically etch through unmasked (e.g., exposed) portions of base dielectric structure 1300 not protected by a mask structure. As a result of the etching process, the backside cavities have a tapering profile with a width that decreases from the opening of the cavity (e.g., at the bottom surface of base dielectric structure 1300) towards the bottom surface of the source or drain regions 702, 704, and 706, according to some embodiments. One or more conductive materials may be deposited within the backside cavities to form backside contacts 1402. For example, backside contacts 1402 may include any of tungsten, ruthenium, molybdenum, or cobalt. Due to the tapering profile of the backside cavities, the width of backside contacts 1402 may be about 3 nm greater, or between 2 nm and 5 nm greater, at the bottom surface of base dielectric structure 1300 compared to the bottom surface of source or drain regions 702, 704, and 706.

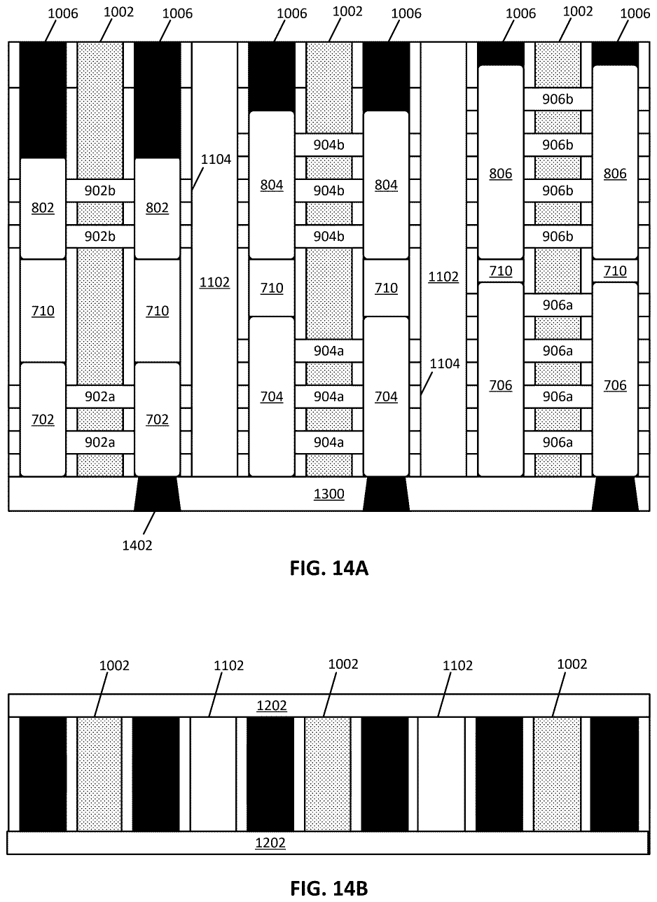

As noted above, many transistor architectures can use the concepts disclosed herein regarding having different numbers of nanoribbons with different widths across different adjacent devices. One transistor architecture is a forksheet arrangement where a dielectric spine extends directly adjacent to (e.g., abutting) the nanoribbons of a given device, such that the gate structure does not extend completely around the nanoribbons. FIG. 15 illustrates a plan view of an example portion of an integrated circuit having a series of adjacent devices where at least one of the devices is a forksheet device. For example, nanoribbons 1502 extend in the first direction between source or drain regions 1508 as part of a first GAA device and nanoribbons 1504 extend in the first direction between source or drain regions 1510 as part of a second GAA device. According to some embodiments, nanosheets 1506 extend between source or drain regions 1512 as part of a forksheet device. In this example, a dielectric wall 1501 acts as both the dielectric spine that directly abuts nanosheets 1506 and also as a gate cut through the gates extending over nanoribbons 1502 and 1504. Source or drain regions 1512 may also directly abut dielectric wall 1501. According to some embodiments, nanosheets 1506 are wider than nanoribbons 1502 and 1504. In this example, the centers of nanoribbons 1502 and 1504 and nanosheets 1506 are aligned as indicated by the dashed line, such that only nanosheets 1506 abut dielectric wall 1501 to form a forksheet device while nanoribbons 1502 and 1504 are spaced from dielectric wall 1501 to form GAA devices. Although not seen in the plan view, the forksheet device with nanosheets 1506 may have a higher number of total nanosheets than the total number of nanoribbons 1504, and the total number of nanoribbons 1504 may be higher than the total number of nanoribbons 1502.

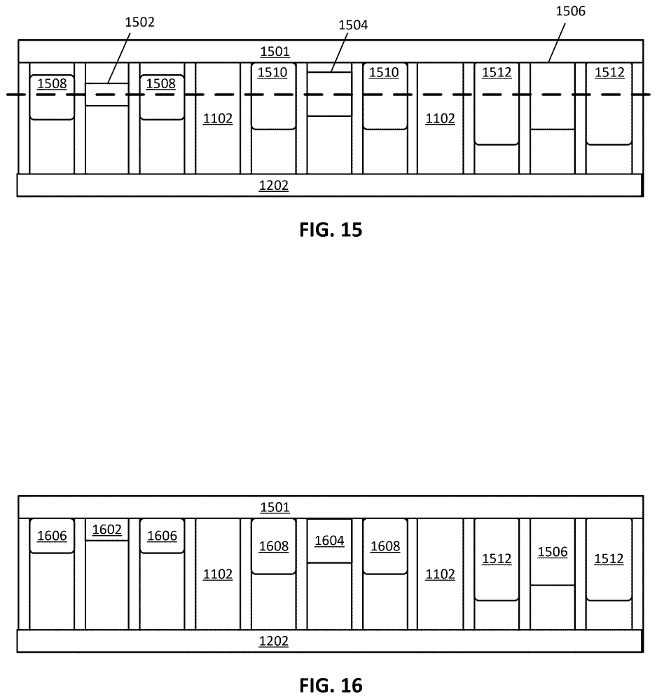

FIG. 16 illustrates another example arrangement of devices in an integrated circuit where all devices along the first direction are forksheet devices. According to some embodiments, nanosheets 1602 extend along the first direction between source or drain regions 1606 as part of a first forksheet device, nanosheets 1604 extend along the first direction between source or drain regions 1608 as part of a second forksheet device, and nanosheets 1506 extend between source or drain regions 1512 as part of a third forksheet device. Each of the nanosheets 1602, 1604, and 1506 from the forksheet devices directly abut dielectric wall 1501, which acts as the dielectric spine for each of the forksheet devices. Additionally, the source or drain regions of each forksheet device also abut dielectric wall 1501. Although not seen in the plan view, the total number of nanosheets 1506 may be higher than the total number of nanosheets 1604, and the total number of nanosheets 1604 may be higher than the total number of nanosheets 1602.

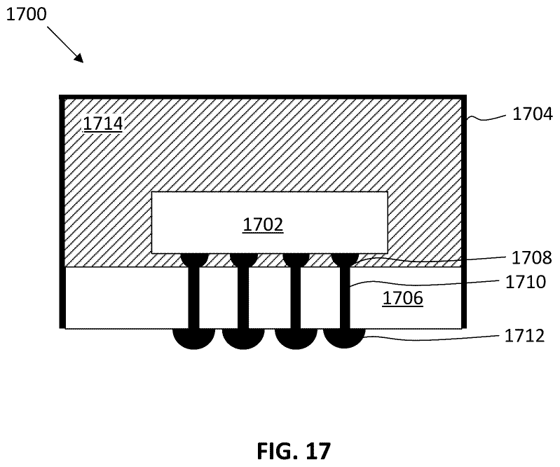

FIG. 17 illustrates an example embodiment of a chip package 1700, in accordance with an embodiment of the present disclosure. As can be seen, chip package 1700 includes one or more dies 1702. One or more dies 1702 may include at least one integrated circuit having semiconductor devices, such as any of the semiconductor devices disclosed herein. One or more dies 1702 may include any other circuitry used to interface with other devices formed on the dies, or other devices connected to chip package 1700, in some example configurations.

As can be further seen, chip package 1700 includes a housing 1704 that is bonded to a package substrate 1706. The housing 1704 may be any standard or proprietary housing, and may provide, for example, electromagnetic shielding and environmental protection for the components of chip package 1700. The one or more dies 1702 may be conductively coupled to a package substrate 1706 using connections 1708, which may be implemented with any number of standard or proprietary connection mechanisms, such as solder bumps, ball grid array (BGA), pins, or wire bonds, to name a few examples. Package substrate 1706 may be any standard or proprietary package substrate, but in some cases includes a dielectric material having conductive pathways (e.g., including conductive vias and lines) extending through the dielectric material between the faces of package substrate 1706, or between different locations on each face. In some embodiments, package substrate 1706 may have a thickness less than 1 millimeter (e.g., between 0.1 millimeters and 0.5 millimeters), although any number of package geometries can be used. Additional conductive contacts 1712 may be disposed at an opposite face of package substrate 1706 for conductively contacting, for instance, a printed circuit board (PCB). One or more vias 1710 extend through a thickness of package substrate 1706 to provide conductive pathways between one or more of connections 1708 to one or more of contacts 1712. Vias 1710 are illustrated as single straight columns through package substrate 1706 for ease of illustration, although other configurations can be used (e.g., damascene, dual damascene, through-silicon via, or an interconnect structure that meanders through the thickness of substrate 1706 to contact one or more intermediate locations therein). In still other embodiments, vias 1710 are fabricated by multiple smaller stacked vias, or are staggered at different locations across package substrate 1706. In the illustrated embodiment, contacts 1712 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1712, to inhibit shorting.

In some embodiments, a mold material 1714 may be disposed around the one or more dies 1702 included within housing 1704 (e.g., between dies 1702 and package substrate 1706 as an underfill material, as well as between dies 1702 and housing 1704 as an overfill material). Although the dimensions and qualities of the mold material 1714 can vary from one embodiment to the next, in some embodiments, a thickness of mold material 1714 is less than 1 millimeter. Example materials that may be used for mold material 1714 include epoxy mold materials, as suitable. In some cases, the mold material 1714 is thermally conductive, in addition to being electrically insulating.

### Example System

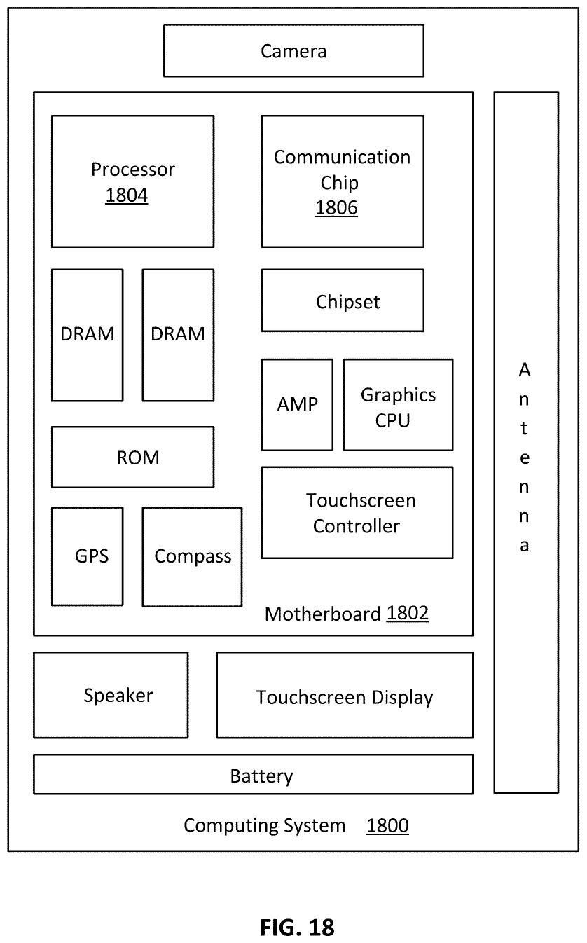

FIG. 18 is an example computing system implemented with one or more of the integrated circuit structures as disclosed herein, in accordance with some embodiments of the present disclosure. As can be seen, the computing system 1800 houses a motherboard 1802. The motherboard 1802 may include a number of components, including, but not limited to, a processor 1804 and at least one communication chip 1806, each of which can be physically and electrically coupled to the motherboard 1802, or otherwise integrated therein. As will be appreciated, the motherboard 1802 may be, for example, any printed circuit board (PCB), whether a main board, a daughterboard mounted on a main board, or the only board of system 1800, etc.

Depending on its applications, computing system 1800 may include one or more other components that may or may not be physically and electrically coupled to the motherboard 1802. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1800 may include one or more integrated circuit structures or devices configured in accordance with an example embodiment (e.g., a module including an integrated circuit device on a substrate, the substrate having semiconductor devices with different numbers of nanoribbons with different widths, as variously provided herein). In some embodiments, multiple functions can be integrated into one or more chips (e.g., for instance, note that the communication chip 1806 can be part of or otherwise integrated into the processor 1804).

The communication chip 1806 enables wireless communications for the transfer of data to and from the computing system 1800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1806 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1800 may include a plurality of communication chips 1806. For instance, a first communication chip 1806 may be dedicated to shorter range wireless communications such as Wi-Fi and Bluetooth and a second communication chip 1806 may be dedicated to longer range wireless communications such as GPS, EDGE, GPRS, CDMA, WiMAX, LTE, Ev-DO, and others.

The processor 1804 of the computing system 1800 includes an integrated circuit die packaged within the processor 1804. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1806 also may include an integrated circuit die packaged within the communication chip 1806. In accordance with some such example embodiments, the integrated circuit die of the communication chip includes one or more semiconductor devices as variously described herein. As will be appreciated in light of this disclosure, note that multi-standard wireless capability may be integrated directly into the processor 1804 (e.g., where functionality of any chips 1806 is integrated into processor 1804, rather than having separate communication chips). Further note that processor 1804 may be a chip set having such wireless capability. In short, any number of processor 1804 and/or communication chips 1806 can be used. Likewise, any one chip or chip set can have multiple functions integrated therein.

In various implementations, the computing system 1800 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1800 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.
Example 1 is an integrated circuit that includes a first plurality of semiconductor nanoribbons extending from a first source or drain region in a first direction, a second plurality of semiconductor nanoribbons extending from a second source or drain region in the first direction, a first gate structure extending over the first plurality of semiconductor nanoribbons in a second direction different from the first direction, and a second gate structure extending over the second plurality of semiconductor nanoribbons in the second direction. The first plurality of semiconductor nanoribbons have a first width in the second direction, and the second plurality of semiconductor nanoribbons have a second width in the second direction that is greater than the first width. The second source or drain region is aligned with the first source or drain region along the first direction. A total number of nanoribbons in the first plurality of semiconductor nanoribbons is less than a total number of nanoribbons in the second plurality of semiconductor nanoribbons.
Example 2 includes the integrated circuit of Example 1, wherein the first plurality of semiconductor bodies and the second plurality of semiconductor bodies comprises germanium, silicon, or any combination thereof.
Example 3 includes the integrated circuit of Example 1 or 2, wherein the second width is between 2 nm and 10 nm greater than the first width.
Example 4 includes the integrated circuit of any one of Examples 1-3, wherein the first and second source or drain regions are both p-type source or drain regions, or are both n-type source or drain regions.
Example 5 includes the integrated circuit of any one of Examples 1-4, further comprising a dielectric structure extending in the second direction between the first source or drain region and the second source or drain region and extending in a third direction along an entire height of the first source or drain region and the second source or drain region.
Example 6 includes the integrated circuit of Example 5, further comprising: a first semiconductor region extending in the first direction from the first source or drain region to the dielectric structure; and a second semiconductor region extending in the first direction from the second source or drain region to the dielectric structure.
Example 7 includes the integrated circuit of any one of Examples 1-6, wherein the total number of semiconductor bodies in the first plurality of semiconductor bodies is one less than the total number of semiconductor bodies in the second plurality of semiconductor bodies.
Example 8 includes the integrated circuit of any one of Examples 1-7, further comprising: a third plurality of semiconductor bodies extending from a third source or drain region in the first direction, the third plurality of semiconductor bodies having a third width in the second direction that is greater than the second width, and the third source or drain region being aligned with the second source or drain region along the first direction; and a third gate structure extending over the third plurality of semiconductor bodies in the second direction. A total number of semiconductor bodies in the second plurality of semiconductor bodies is less than a total number of semiconductor bodies in the third plurality of semiconductor bodies.
Example 9 includes the integrated circuit of any one of Examples 1-7, further comprising: a third plurality of semiconductor bodies extending from a third source or drain region in the first direction, the third plurality of semiconductor bodies having the first width in the second direction, and the third source or drain region being arranged beneath the first source or drain region in a third direction orthogonal to the first and second directions; and a fourth plurality of semiconductor bodies extending from a fourth source or drain region in the first direction, the fourth plurality of semiconductor bodies having the second width in the second direction, and the fourth source or drain region being arranged beneath the second source or drain region in the third direction. The third plurality of semiconductor bodies have a same total number of semiconductor bodies as the first plurality of semiconductor bodies, and the fourth plurality of semiconductor bodies have a same total number of semiconductor bodies as the second plurality of semiconductor bodies.
Example 10 includes the integrated circuit of Example 9, wherein the first and second source or drain regions are both n-type source or drain regions, and the third and fourth source or drain regions are both p-type source or drain regions, or vice-versa.
Example 11 includes the integrated circuit of any one of Examples 1-10, further comprising a dielectric spine extending along the first direction through the second gate structure and along a third direction through an entire height of the second gate structure, wherein the second plurality of semiconductor bodies directly abut the dielectric spine.
Example 12 includes the integrated circuit of Example 11, wherein the dielectric spine extends along the first direction to cut across the first gate structure and extends along the third direction through an entire height of the first gate structure.
Example 13 includes the integrated circuit of any one of Examples 1-12, wherein the first plurality of semiconductor bodies has a first center at a central location across its first width, the second plurality of semiconductor bodies has a second center at a central location across its second width, and a plane extending along the first direction and along a third direction orthogonal to the first and second directions passes through both the first center and the second center.
Example 14 includes the integrated circuit of any one of Examples 1-13, wherein the first plurality of semiconductor bodies are nanoribbons, nanosheets, and/or nanowires, and the second plurality of semiconductor bodies are nanoribbons, nanosheets, and/or nanowires.
Example 15 is a die that includes the integrated circuit of any one of Examples 1-14.
Example 16 is an electronic device that includes a chip package having one or more dies. At least one of the one or more dies includes a first semiconductor device having a first plurality of semiconductor nanoribbons extending from a first source or drain region to a second source or drain region in a first direction, and a second semiconductor device having a second plurality of semiconductor nanoribbons extending from a third source or drain region to a fourth source or drain region in the first direction. The first semiconductor device includes a first gate structure extending over the first plurality of semiconductor nanoribbons in a second direction different from the first direction, and the second semiconductor device includes a second gate structure extending over the second plurality of semiconductor nanoribbons in the second direction. The first plurality of semiconductor nanoribbons have a first width in the second direction, and the second plurality of semiconductor nanoribbons have a second width in the second direction that is greater than the first width. A total number of nanoribbons in the first plurality of semiconductor nanoribbons is less than a total number of nanoribbons in the second plurality of semiconductor nanoribbons.
Example 17 includes the electronic device of Example 16, wherein the first plurality of semiconductor nanoribbons and the second plurality of semiconductor nanoribbons comprises germanium, silicon, or any combination thereof.
Example 18 includes the electronic device of Example 16 or 17, wherein the second width is between 2 nm and 10 nm greater than the first width.
Example 19 includes the electronic device of any one of Examples 16-18, wherein the first, second, third, and fourth source or drain regions are all p-type source or drain regions, or are all n-type source or drain regions.
Example 20 includes the electronic device of any one of Examples 16-19, wherein the at least one of the one or more dies further comprises a dielectric structure extending in the second direction between the first source or drain region and the third source or drain region and extending in a third direction along an entire height of the first source or drain region and the third source or drain region.
Example 21 includes the electronic device of Example 20, wherein the at least one of the one or more dies further comprises: a first semiconductor region extending in the first direction from the first source or drain region to the dielectric structure; and a second semiconductor region extending in the first direction from the third source or drain region to the dielectric structure.
Example 22 includes the electronic device of any one of Examples 16-21, wherein the total number of nanoribbons in the first plurality of semiconductor nanoribbons is one less than the total number of nanoribbons in the second plurality of semiconductor nanoribbons.
Example 23 includes the electronic device of any one of Examples 16-22, wherein the at least one of the one or more dies further comprises a third semiconductor device having a third plurality of semiconductor nanoribbons extending from a fifth source or drain region to a sixth source or drain region in the first direction. The third plurality of semiconductor nanoribbons have a third width in the second direction that is greater than the second width. The at least one of the one or more dies further comprises a third gate structure extending over the third plurality of semiconductor nanoribbons in the second direction. A total number of nanoribbons in the second plurality of semiconductor nanoribbons is less than a total number of nanoribbons in the third plurality of semiconductor nanoribbons.
Example 24 includes the electronic device of any one of Examples 16-22, wherein the at least one of the one or more dies further comprises: a third semiconductor device having a third plurality of semiconductor nanoribbons extending from a fifth source or drain region to a sixth source or drain region in the first direction; and a fourth semiconductor device having a fourth plurality of semiconductor nanoribbons extending from a seventh source or drain region to an eighth source or drain region in the first direction. The third plurality of semiconductor nanoribbons have the first width in the second direction and the fourth plurality of semiconductor nanoribbons have the second width in the second direction. The fifth source or drain region is arranged beneath the first source or drain region in a third direction orthogonal to the first and second directions, and the sixth source or drain region is arranged beneath the second source or drain region in the third direction. The seventh source or drain region is arranged beneath the third source or drain region in the third direction, and the eighth source or drain region is arranged beneath the fourth source or drain region in the third direction. The third plurality of semiconductor nanoribbons have a same total number of nanoribbons as the first plurality of semiconductor nanoribbons, and the fourth plurality of semiconductor nanoribbons have a same total number of nanoribbons as the second plurality of semiconductor nanoribbons.
Example 25 includes the electronic device of Example 24, wherein the first, second, third, and fourth source or drain regions are all n-type source or drain regions, and the fifth, sixth, seventh, and eighth source or drain regions are all p-type source or drain regions, or vice-versa.
Example 26 includes the electronic device of any one of Examples 16-25, wherein the at least one of the one or more dies further comprises a dielectric spine extending along the first direction through the second gate structure and along a third direction through an entire height of the second gate structure, wherein the second plurality of semiconductor nanoribbons directly abut the dielectric spine.
Example 27 includes the electronic device of Example 26, wherein the dielectric spine extends along the first direction to cut across the first gate structure and extends along the third direction through an entire height of the first gate structure.
Example 28 includes the electronic device of any one of Examples 16-27, wherein the first plurality of semiconductor nanoribbons has a first center at a central location across its first width, the second plurality of semiconductor nanoribbons has a second center at a central location across its second width, and a plane extending along the first direction and along a third direction orthogonal to the first and second directions passes through both the first center and the second center.
Example 29 includes the electronic device of any one of Examples 16-28, further comprising a printed circuit board, wherein the chip package is attached to the printed circuit board.
Example 30 is an integrated circuit that includes a first plurality of semiconductor nanoribbons extending from a first source or drain region in a first direction, a second plurality of semiconductor nanoribbons extending from a second source or drain region in the first direction, and a dielectric structure extending along a second direction different from the first direction and arranged substantially equidistant between the first source or drain region and the second source or drain region along the first direction. The first plurality of semiconductor nanoribbons have a first width in the second direction, and the second plurality of semiconductor nanoribbons have a second width in the second direction that is greater than the first width. The second source or drain region is aligned with the first source or drain region along the first direction. A total number of nanoribbons in the first plurality of semiconductor nanoribbons is less than a total number of nanoribbons in the second plurality of semiconductor nanoribbons.
Example 31 includes the integrated circuit of Example 30, wherein the first plurality of semiconductor nanoribbons and the second plurality of semiconductor nanoribbons comprises germanium, silicon, or any combination thereof.
Example 32 includes the integrated circuit of Example 30 or 31, wherein the second width is between 2 nm and 10 nm greater than the first width.
Example 33 includes the integrated circuit of any one of Examples 30-32, wherein the first and second source or drain regions are both p-type source or drain regions, or are both n-type source or drain regions.
Example 34 includes the integrated circuit of any one of Examples 30-33, wherein the dielectric structure further extends in a third direction along an entire height of the first source or drain region and the second source or drain region.
Example 35 includes the integrated circuit of any one of Examples 30-34, further comprising: a first semiconductor region extending in the first direction from the first source or drain region to the dielectric structure; and a second semiconductor region extending in the first direction from the second source or drain region to the dielectric structure.
Example 36 includes the integrated circuit of any one of Examples 30-35, wherein the total number of nanoribbons in the first plurality of semiconductor nanoribbons is one less than the total number of nanoribbons in the second plurality of semiconductor nanoribbons.
Example 37 includes the integrated circuit of any one of Examples 30-36, further comprising a third plurality of semiconductor nanoribbons extending from a third source or drain region in the first direction. The third plurality of semiconductor nanoribbons have a third width in the second direction that is greater than the second width. The third source or drain region is aligned with the second source or drain region along the first direction. A total number of nanoribbons in the second plurality of semiconductor nanoribbons is less than a total number of nanoribbons in the third plurality of semiconductor nanoribbons.
Example 38 includes the integrated circuit of any one of Examples 30-36, further comprising a third plurality of semiconductor nanoribbons extending from a third source or drain region in the first direction, and a fourth plurality of semiconductor nanoribbons extending from a fourth source or drain region in the first direction. The third plurality of semiconductor nanoribbons have the first width in the second direction, and the fourth plurality of semiconductor nanoribbons having the second width in the second direction. The third source or drain region is arranged beneath the first source or drain region in a third direction orthogonal to the first and second directions, and the fourth source or drain region is arranged beneath the second source or drain region in the third direction. The third plurality of semiconductor nanoribbons has a same total number of nanoribbons as the first plurality of semiconductor nanoribbons, and the fourth plurality of semiconductor nanoribbons has a same total number of nanoribbons as the second plurality of semiconductor nanoribbons.
Example 39 includes the integrated circuit of Example 38, wherein the first and second source or drain regions are both n-type source or drain regions, and the third and fourth source or drain regions are both p-type source or drain regions, or vice-versa.
Example 40 includes the integrated circuit of Example 38 or 39, wherein the dielectric structure further extends in the third direction such that it is arranged substantially equidistant between the third source or drain region and the fourth source or drain region along the first direction.
Example 41 includes the integrated circuit of any one of Examples 30-40, further comprising a first gate structure extending over the first plurality of semiconductor nanoribbons in the second direction, and a second gate structure extending over the second plurality of semiconductor nanoribbons in the second direction.
Example 42 includes the integrated circuit of Example 41, further comprising a dielectric spine extending along the first direction through the second gate structure and along a third direction through an entire height of the second gate structure, wherein the second plurality of semiconductor nanoribbons directly abut the dielectric spine.
Example 43 includes the integrated circuit of Example 42, wherein the dielectric spine extends along the first direction to cut across the first gate structure and extends along the third direction through an entire height of the first gate structure.
Example 44 is a die that includes the integrated circuit of any one of Examples 30-43.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first plurality of semiconductor bodies extending from a first source or drain region in a first direction, the first plurality of semiconductor bodies having a first width in a second direction different from the first direction;
a second plurality of semiconductor bodies extending from a second source or drain region in the first direction, the second plurality of semiconductor bodies having a second width in the second direction that is greater than the first width, and the second source or drain region being aligned with the first source or drain region along the first direction; and
a first gate structure extending over the first plurality of semiconductor bodies in the second direction, and a second gate structure extending over the second plurality of semiconductor bodies in the second direction;
wherein a total number of bodies in the first plurality of semiconductor bodies is less than a total number of bodies in the second plurality of semiconductor bodies.

2. The integrated circuit of claim 1, further comprising a dielectric structure extending in the second direction between the first source or drain region and the second source or drain region and extending in a third direction along an entire height of the first source or drain region and the second source or drain region.

3. The integrated circuit of claim 2, further comprising:
a first semiconductor region extending in the first direction from the first source or drain region to the dielectric structure; and
a second semiconductor region extending in the first direction from the second source or drain region to the dielectric structure.

4. The integrated circuit of claim 1, further comprising:
a third plurality of semiconductor bodies extending from a third source or drain region in the first direction, the third plurality of semiconductor bodies having a third width in the second direction that is greater than the second width, and the third source or drain region being aligned with the second source or drain region along the first direction; and
a third gate structure extending over the third plurality of semiconductor bodies in the second direction;
wherein a total number of semiconductor bodies in the second plurality of semiconductor bodies is less than a total number of semiconductor bodies in the third plurality of semiconductor bodies.

5. The integrated circuit of claim 1, further comprising:
a third plurality of semiconductor bodies extending from a third source or drain region in the first direction, the third plurality of semiconductor bodies having the first width in the second direction, and the third source or drain region being arranged beneath the first source or drain region in a third direction orthogonal to the first and second directions; and
a fourth plurality of semiconductor bodies extending from a fourth source or drain region in the first direction, the fourth plurality of semiconductor bodies having the second width in the second direction, and the fourth source or drain region being arranged beneath the second source or drain region in the third direction,
wherein the third plurality of semiconductor bodies have a same total number of semiconductor bodies as the first plurality of semiconductor bodies, and the fourth plurality of semiconductor bodies have a same total number of semiconductor bodies as the second plurality of semiconductor bodies.

6. The integrated circuit of claim 1, further comprising a dielectric spine extending along the first direction through the second gate structure and along a third direction through an entire height of the second gate structure, wherein the second plurality of semiconductor bodies directly abut the dielectric spine.

7. The integrated circuit of claim 6, wherein the dielectric spine extends along the first direction to cut across the first gate structure and extends along the third direction through an entire height of the first gate structure.

8. The integrated circuit of claim 1, wherein the first plurality of semiconductor bodies has a first center at a central location across its first width, the second plurality of semiconductor bodies has a second center at a central location across its second width, and a plane extending along the first direction and along a third direction orthogonal to the first and second directions passes through both the first center and the second center.

9. An electronic device, comprising:
a chip package comprising one or more dies, at least one of the one or more dies comprising
a first semiconductor device having a first plurality of semiconductor nanoribbons extending from a first source or drain region to a second source or drain region in a first direction, the first plurality of semiconductor nanoribbons having a first width in a second direction different from the first direction, and a first gate structure extending over the first plurality of semiconductor nanoribbons in the second direction;
a second semiconductor device having a second plurality of semiconductor nanoribbons extending from a third source or drain region to a fourth source or drain region in the first direction, the second plurality of semiconductor nanoribbons having a second width in the second direction that is greater than the first width, and a second gate structure extending over the second plurality of semiconductor nanoribbons in the second direction;
wherein a total number of nanoribbons in the first plurality of semiconductor nanoribbons is less than a total number of nanoribbons in the second plurality of semiconductor nanoribbons.

10. The electronic device of claim 9, wherein the at least one of the one or more dies further comprises a dielectric structure extending in the second direction between the first source or drain region and the third source or drain region and extending in a third direction along an entire height of the first source or drain region and the third source or drain region.

11. The electronic device of claim 10, wherein the at least one of the one or more dies further comprises:
a first semiconductor region extending in the first direction from the first source or drain region to the dielectric structure; and
a second semiconductor region extending in the first direction from the third source or drain region to the dielectric structure.

12. The electronic device of claim 9, wherein the at least one of the one or more dies further comprises:
a third semiconductor device having a third plurality of semiconductor nanoribbons extending from a fifth source or drain region to a sixth source or drain region in the first direction, the third plurality of semiconductor nanoribbons having the first width in the second direction, the fifth source or drain region being arranged beneath the first source or drain region in a third direction orthogonal to the first and second directions, and the sixth source or drain region being arranged beneath the second source or drain region in the third direction; and
a fourth semiconductor device having a fourth plurality of semiconductor nanoribbons extending from a seventh source or drain region to an eighth source or drain region in the first direction, the fourth plurality of semiconductor nanoribbons having the second width in the second direction, the seventh source or drain region being arranged beneath the third source or drain region in the third direction, and the eighth source or drain region being arranged beneath the fourth source or drain region in the third direction,
wherein the third plurality of semiconductor nanoribbons have a same total number of nanoribbons as the first plurality of semiconductor nanoribbons, and the fourth plurality of semiconductor nanoribbons have a same total number of nanoribbons as the second plurality of semiconductor nanoribbons.

13. The electronic device of claim 9, wherein the at least one of the one or more dies further comprises a dielectric spine extending along the first direction through the second gate structure and along a third direction through an entire height of the second gate structure, wherein the second plurality of semiconductor nanoribbons directly abut the dielectric spine.

14. An integrated circuit comprising:
a first plurality of semiconductor nanoribbons extending from a first source or drain region in a first direction, the first plurality of semiconductor nanoribbons having a first width in a second direction different from the first direction;
a second plurality of semiconductor nanoribbons extending from a second source or drain region in the first direction, the second plurality of semiconductor nanoribbons having a second width in the second direction that is greater than the first width, and the second source or drain region being aligned with the first source or drain region along the first direction; and
a dielectric structure extending along the second direction and arranged substantially equidistant between the first source or drain region and the second source or drain region along the first direction;
wherein a total number of nanoribbons in the first plurality of semiconductor nanoribbons is less than a total number of nanoribbons in the second plurality of semiconductor nanoribbons.

15. The integrated circuit of claim 14, further comprising:
a first semiconductor region extending in the first direction from the first source or drain region to the dielectric structure; and
a second semiconductor region extending in the first direction from the second source or drain region to the dielectric structure.

16. The integrated circuit of claim 14, wherein the total number of nanoribbons in the first plurality of semiconductor nanoribbons is one less than the total number of nanoribbons in the second plurality of semiconductor nanoribbons.

17. The integrated circuit of claim 14, further comprising:
a third plurality of semiconductor nanoribbons extending from a third source or drain region in the first direction, the third plurality of semiconductor nanoribbons having a third width in the second direction that is greater than the second width, and the third source or drain region being aligned with the second source or drain region along the first direction,
wherein a total number of nanoribbons in the second plurality of semiconductor nanoribbons is less than a total number of nanoribbons in the third plurality of semiconductor nanoribbons.

18. The integrated circuit of claim 14, further comprising:
a third plurality of semiconductor nanoribbons extending from a third source or drain region in the first direction, the third plurality of semiconductor nanoribbons having the first width in the second direction, and the third source or drain region being arranged beneath the first source or drain region in a third direction orthogonal to the first and second directions; and
a fourth plurality of semiconductor nanoribbons extending from a fourth source or drain region in the first direction, the fourth plurality of semiconductor nanoribbons having the second width in the second direction, and the fourth source or drain region being arranged beneath the second source or drain region in the third direction,
wherein the third plurality of semiconductor nanoribbons have a same total number of nanoribbons as the first plurality of semiconductor nanoribbons, and the fourth plurality of semiconductor nanoribbons have a same total number of nanoribbons as the second plurality of semiconductor nanoribbons.

19. The integrated circuit of claim 14, further comprising a first gate structure extending over the first plurality of semiconductor nanoribbons in the second direction, and a second gate structure extending over the second plurality of semiconductor nanoribbons in the second direction.

20. The integrated circuit of claim 19, further comprising a dielectric spine extending along the first direction through the second gate structure and along a third direction through an entire height of the second gate structure, wherein the second plurality of semiconductor nanoribbons directly abut the dielectric spine.
